(19) United States
(12) Patent Application Publication
(10) Pub. No.: US 2023/0378013 A1
(43) Pub. Date: Nov. 23, 2023

(54) SEMICONDUCTOR DEVICE

(71) Applicant: ROHM CO., LTD., Kyoto-shi (JP)

(72) Inventor: Kengo OHMORI, Kyoto-shi (JP)

(73) Assignee: ROHM CO., LTD., Kyoto-shi (JP)

(21) Appl. No.: 18/197,728

(22) Filed: May 16, 2023

(30) Foreign Application Priority Data
May 20, 2022 (JP) 2022-083314

(51) Int. Cl. H01L 23/31; H01L 23/00

(52) U.S. Cl. CPC H01L 23/3192; H01L 24/40; H01L 24/37; H01L 24/32; H01L 24/73; H01L 23/3171; H01L 2224/40247; H01L 2224/40475; H01L 2224/37147; H01L 2224/32245; H01L 2224/73263; H01L 2924/13091; H01L 2924/13064

(57) ABSTRACT

A semiconductor device includes a semiconductor element including a transistor, a gate interconnect electrically connected to a gate electrode and extending in a first direction, two connection pads electrically connected to a source or drain electrode and separated in a second direction orthogonal to the first direction in plan view, a passivation layer formed on the gate interconnect, and an organic film layer formed on the passivation layer, a conductive bonding material disposed on the semiconductor element and at least partially overlapping the gate interconnect and the connection pads in plan view, and a conductive member disposed on the conductive bonding material. The connection pads are electrically connected to the conductive member via the conductive bonding material. The gate interconnect is disposed between the connection pads in plan view. The passivation layer is separated from the conductive bonding material by the organic film layer being thicker than the passivation layer.

### CROSS-REFERENCE TO RELATED APPLICATION

The application claims priority to Japanese Patent Application No. 2022-083314, filed on May 20, 2022, the entire disclosure of which is hereby incorporated by reference in its entirety.

### BACKGROUND

### 1. Field

The following description relates to a semiconductor device.

### 2. Description of Related Art

A semiconductor package may be provided with an electrical connection by connecting a plate-shaped metal clip to the upper surface of a semiconductor element (die). The use of such a metal clip improves the heat dissipation property of the package and reduces the resistance of the package as compared to when conventional wire bonding is used.

Japanese National Phase Laid-Open Patent Publication No. 2018-504788 discloses a method for die and clip attachment. The die is mounted on a substrate, and then the clip is mounted on the die and the substrate to form a substrate-die-clip package.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

A conductive member such as a metal clip is connected to a semiconductor element having an upper surface on which an insulating passivation layer and a connection pad exposed from the passivation layer are formed. A conductive bonding material such as solder may be disposed between the upper surface of the semiconductor element and the conductive member and then undergo a thermal process (e.g., reflowing of solder) to ensure the electrical connection between the connection pad and the conductive member.

However, changes in the temperature of the conductive bonding material during the thermal process may cause a crack to be formed in the passivation layer that is in direct contact with the conductive bonding material disposed below the conductive member. In particular, when a plurality of interconnects (electrodes) originally having different potentials are disposed below the conductive member and insulated from each other, if a crack is formed in the passivation layer, covering the interconnects, the crack may cause a short circuit between the interconnects.

An aspect of the present disclosure is a semiconductor device that includes a semiconductor element, a conductive bonding material, and a conductive member. The semiconductor element includes a transistor including a gate electrode, a source electrode, and a drain electrode, a gate interconnect electrically connected to the gate electrode and extending in a first direction, a first connection pad and a second connection pad electrically connected to one of the source electrode and the drain electrode and separated from each other in a second direction orthogonal to the first direction in plan view, a passivation layer formed on the gate interconnect, and an organic film layer formed on the passivation layer. The conductive bonding material is disposed on the semiconductor element and at least partially overlapping with the gate interconnect, the first connection pad, and the second connection pad in plan view. The conductive member is disposed on the conductive bonding material. The first connection pad and the second connection pad are electrically connected to the conductive member via the conductive bonding material. The gate interconnect is disposed between the first connection pad and the second connection pad in plan view. The passivation layer formed on the gate interconnect is separated from the conductive bonding material by the organic film layer that is greater in thickness than the passivation layer.

Other features and aspects will be apparent from the following detailed description, the drawings, and the claims.

### BRIEF DESCRIPTION OF THE DRAWINGS

FIG. 1 is a schematic cross-sectional view showing an example of a semiconductor device in a first embodiment.

FIG. 2 is a schematic plan view showing an example of a semiconductor element in the semiconductor device of the first embodiment.

FIG. 3 is a schematic plan view of the semiconductor device showing an example of arrangement of a conductive member and the semiconductor element shown in FIG. 2.

FIG. 4 is a schematic cross-sectional view of the semiconductor device showing the bonding of the semiconductor element to the conductive member via a conductive bonding material.

FIG. 5 is a schematic cross-sectional view showing an example of a transistor included in the semiconductor element shown in FIG. 2.

FIG. 6 is a schematic cross-sectional view showing a comparative example of a semiconductor device.

FIG. 7 is a schematic cross-sectional view showing another comparative example of a semiconductor device.

FIG. 8 is a schematic plan view showing an example of a semiconductor device in a second embodiment.

FIG. 9 is a schematic plan view showing an example of a semiconductor element in the semiconductor device of the second embodiment.

FIG. 10 is a schematic cross-sectional view showing an example of a transistor included in the semiconductor element shown in FIG. 9.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

Embodiments of a semiconductor device according to the present disclosure will be described below with reference to the drawings. In the drawings, elements may not be drawn to scale for simplicity and clarity of illustration. To facilitate understanding, hatching may be omitted from a cross-sectional view, and hatching may be added to a plan view. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

### First Embodiment

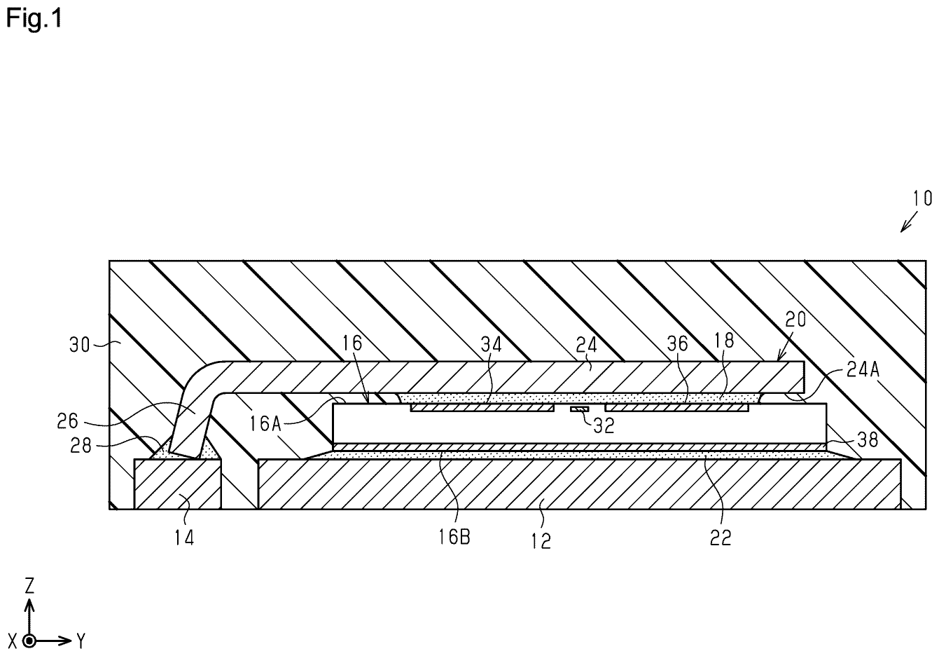

FIG. 1 is a schematic cross-sectional view showing an example of a semiconductor device 10 in a first embodiment. The semiconductor device 10 may have, for example, a structure that uses a lead frame. In the example shown in FIG. 1, the semiconductor device 10 includes a conductive plate 12 and a conductive terminal 14. The conductive plate 12 and the conductive terminal 14 may have any shape (any outer shape) and any thickness. The thickness refers to the dimension in the Z-axis direction shown in FIG. 1 unless otherwise clearly specified from the context. In the example shown in FIG. 1, each of the conductive plate 12 and the conductive terminal 14 may be flat and plate-shaped. The conductive terminal 14 is electrically insulated from the conductive plate 12. The conductive plate 12 and the conductive terminal 14 are formed of, for example, a metal material such as copper (Cu) or aluminum (Al).

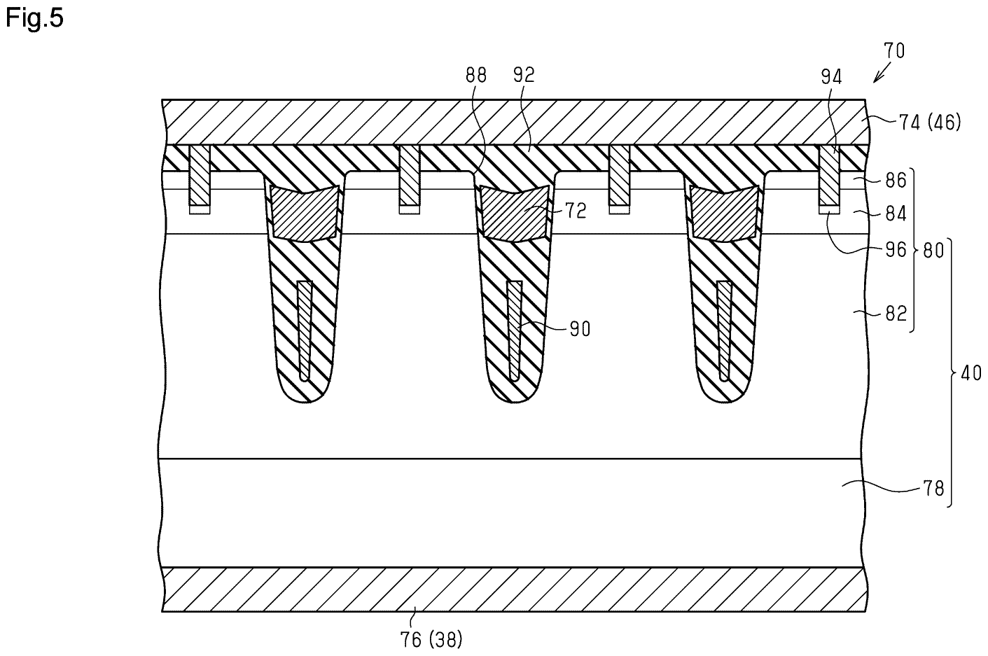

The semiconductor device 10 includes a semiconductor element 16, a conductive bonding material 18 disposed on the semiconductor element 16, and a conductive member 20 disposed on the conductive bonding material 18. The semiconductor device 10 of the present disclosure may be applied to a semiconductor element 16 that includes any transistor formed from a semiconductor material such as silicon (Si), silicon carbide (SiC), gallium arsenide (GaAs), or gallium nitride (GaN). The semiconductor element 16 may include a metal-oxide-semiconductor field effect transistor (MOSFET), a metal-insulator-semiconductor field effect transistor (MISFET), or a high-electron-mobility transistor (HEMT). The semiconductor element 16 of the present embodiment may be a semiconductor chip (die) that includes a transistor 70, which will be described later with reference to FIG. 5.

The semiconductor element 16 includes an upper surface 16A in contact with the conductive bonding material 18 and a bottom surface 16B opposite to the upper surface 16A. The semiconductor element 16 is mounted on the conductive plate 12. The semiconductor device 10 may further include a conductive bonding material 22 that bonds the bottom surface 16B of the semiconductor element 16 to the conductive plate 12.

The conductive member 20 may have any shape (any outer shape) and any thickness. In the example shown in FIG. 1, the conductive member 20 may be in the form of a single bent metal plate. The conductive member 20 having such a structure may also be referred to as a clip. The conductive member 20 may be formed of, for example, Cu. In this case, the conductive member 20 may be referred to as a Cu clip. The conductive member 20 may include a first connecting part 24 and a second connecting part 26. The first connecting part 24 includes a flat bonding surface 24A facing the upper surface 16A of the semiconductor element 16. The conductive bonding material 18 is disposed between the upper surface 16A of the semiconductor element 16 and the bonding surface 24A of the first connecting part 24 in contact with both of the surfaces 16A and 24A. The second connecting part 26 may extend in a direction intersecting the bonding surface 24A of the first connecting part 24 so as to be bonded to the conductive terminal 14. The semiconductor device 10 may further include a conductive bonding material 28 that bonds the second connecting part 26 to the conductive terminal 14. The second connecting part 26 is formed integrally with the first connecting part 24.

In an example, the conductive bonding materials 18, 22, and 28 may be solder or conductive paste. The solder may be lead (Pb)-free solder such as a tin (Sn)-silver (Ag)-copper (Cu)-based solder or may be lead-containing solder such as a Sn—Pb—Ag-based solder. The conductive paste may be, for example, an Ag paste. The semiconductor device 10 may further include an encapsulation member 30 that encapsulates the semiconductor element 16.

The encapsulation member 30 may be formed from an insulative resin material such as an epoxy resin. In an example, the encapsulation member 30 may be formed by molding the insulative resin material.

Details of Semiconductor Element

The semiconductor element 16 includes a gate interconnect 32, a first connection pad 34, and a second connection pad 36. The gate interconnect 32 is disposed between the first connection pad 34 and the second connection pad 36 in plan view and extends in an X-axis direction. The term “plan view” used in the present disclosure refers to a view of an object (semiconductor device 10 or component of semiconductor device 10) in a Z-axis direction when the XYZ-axes are orthogonal to each other. In this specification, the X-axis direction is also referred to as a first direction. In the present embodiment, the semiconductor element 16 may further include a bottom electrode 38. The bottom electrode 38 includes the bottom surface 16B of the semiconductor element 16. In an example, the gate interconnect 32, the first connection pad 34, the second connection pad 36, and the bottom electrode 38 may be formed from at least one of titanium (Ti), nickel (Ni), gold (Au), silver (Ag), copper (Cu), aluminum (Al), and an AlCu alloy.

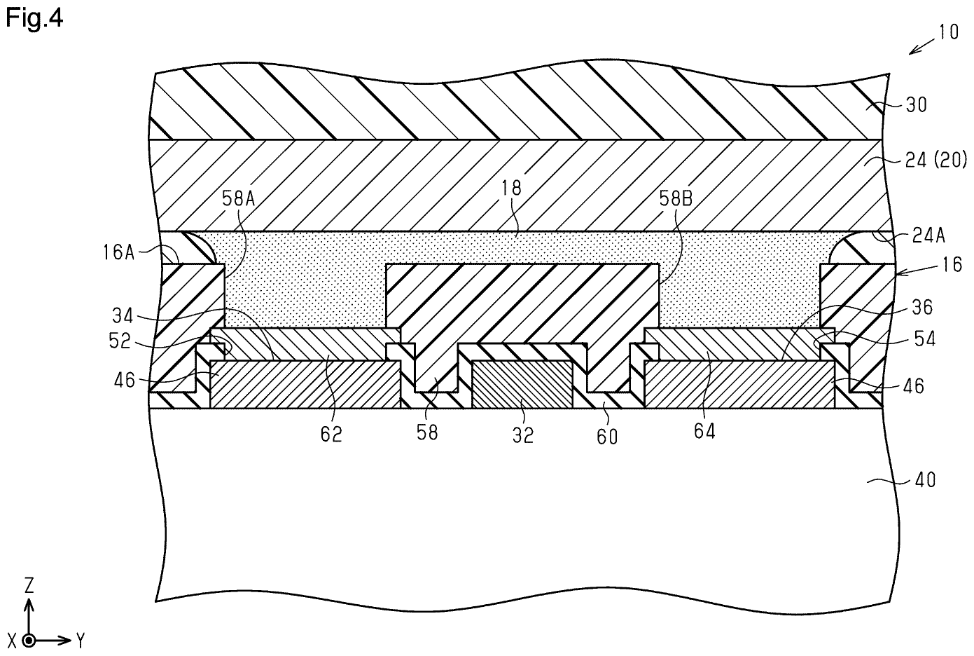

The gate interconnect 32, the first connection pad 34, and the second connection pad 36 are disposed below the flat bonding surface 24A of the first connecting part 24. As schematically shown in FIG. 1, the first connection pad 34 and the second connection pad 36 are electrically connected to the conductive member 20 via the conductive bonding material 18, whereas the gate interconnect 32 is electrically disconnected from the conductive member 20. As a result, the first connection pad 34 and the second connection pad 36 have the same potential. The gate interconnect 32 may differ in potential from the first connection pad 34 and the second connection pad 36. More specifically, the first connection pad 34 and the second connection pad 36 are electrically connected to the flat bonding surface 24A of the first connecting part 24 via the conductive bonding material 18. The cross-sectional structure of the semiconductor element 16 shown in FIG. 1 is simplified for facilitating description. The cross-sectional structure of the semiconductor element 16 will be described in detail later with reference to FIG. 4.

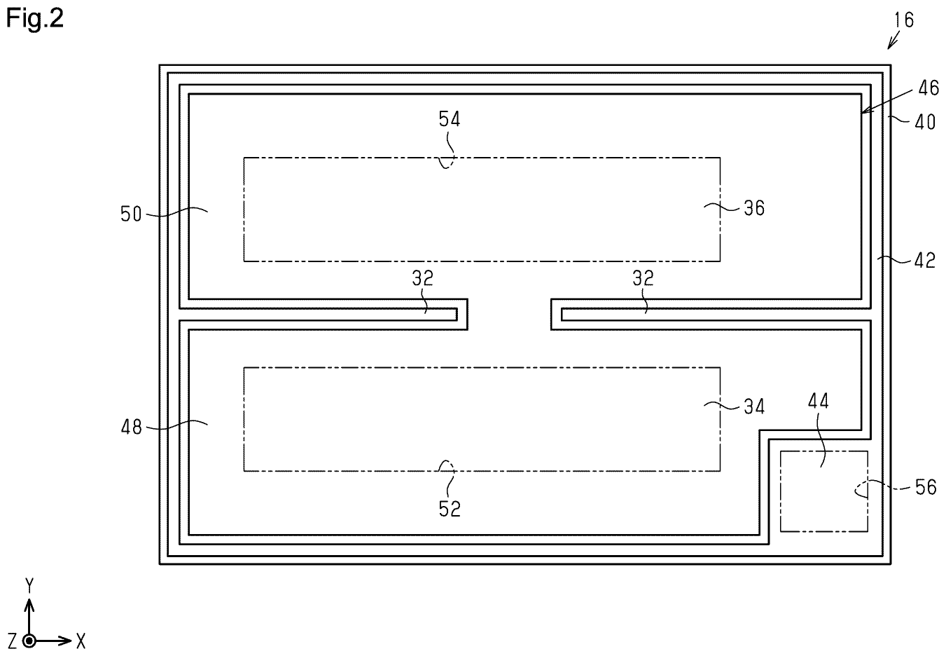

FIG. 2 is a schematic plan view showing an example of the semiconductor element 16. The semiconductor element 16 includes a semiconductor layer 40. The semiconductor layer 40 may be rectangular in plan view.

As shown in FIG. 2, the semiconductor element 16 may further include a peripheral gate interconnect 42 extending along the rectangular edges of the semiconductor layer 40. The peripheral gate interconnect 42 is not shown in FIG. 1 for simplicity and clarity of description. In the example shown in FIG. 2, the gate interconnect 32 extends in the X-axis direction and is connected to a portion of the peripheral gate interconnect 42 extending in a Y-axis direction. In this specification, the Y-axis direction is also referred to as a second direction. As shown in FIG. 2, the gate interconnect 32 may at least partially cross a central portion of the semiconductor element 16 in plan view. The semiconductor element 16 may further include a gate pad 44 electrically connected to the peripheral gate interconnect 42.

The semiconductor element 16 may further include a source interconnect 46 that is surrounded by the peripheral gate interconnect 42 in plan view and separated from the gate interconnect 32, the peripheral gate interconnect 42, and the gate pad 44. The source interconnect 46 is surrounded by the peripheral gate interconnect 42 in plan view and is separated from the gate interconnect 32, the peripheral gate interconnect 42, and the gate pad 44. The source interconnect 46 may include a first part 48 and a second part 50 that are separated in the Y-axis direction by the gate interconnect 32 extending in the X-axis direction. In the example shown in FIG. 2, the first part 48 and the second part 50 may be connected to each other at a central portion of the semiconductor element 16 where the gate interconnect 32 is divided.

To facilitate understanding, FIG. 2 does not show an organic film layer 58 and a passivation layer 60, which will be described later with reference to FIG. 4. In FIG. 2, the double-dashed lines indicate pad openings 52, 54, and 56 formed in the passivation layer 60. The pad opening 52 and the pad opening 54 are respectively formed on the first part 48 and the second part 50 of the source interconnect 46. The pad opening 56 is formed on the gate pad 44.

The first connection pad 34 is the portion of the source interconnect 46 exposed from the pad opening 52. Therefore, the first connection pad 34 is electrically connected to the source interconnect 46. In this specification, the pad opening 52 is also referred to as a first pad opening. The second connection pad 36 is the portion of the source interconnect 46 exposed from the pad opening 54. Therefore, the second connection pad 36 is electrically connected to the source interconnect 46. In this specification, the pad opening 54 is also referred to as a second pad opening.

The first connection pad 34 and the second connection pad 36 are separated from each other in the Y-axis direction. The gate interconnect 32 is disposed between the first connection pad 34 and the second connection pad 36 in plan view and is separated from the first connection pad 34 and second connection pad 36 in the Y-axis direction.

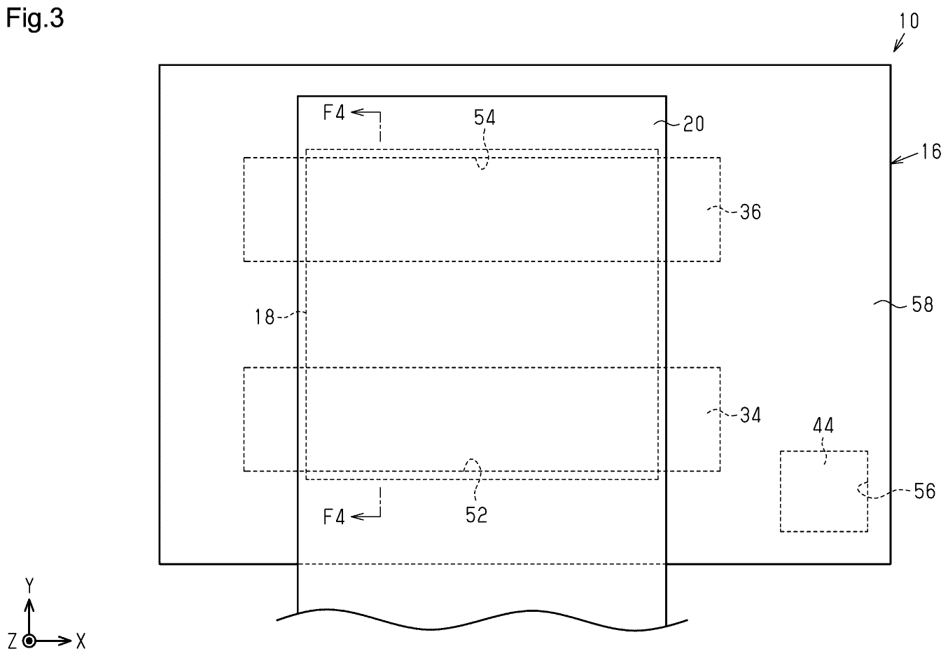

FIG. 3 is a schematic plan view of the semiconductor device 10 showing an example of arrangement of the semiconductor element 16 and the conductive member 20. FIG. 3 shows the organic film layer 58 (refer to FIG. 4) included in the semiconductor element 16. Although not shown, the gate pad 44 may also be connected to another conductive member.

As shown in FIG. 3, the conductive member 20 is disposed so as to at least partially overlap with the first connection pad 34 and the second connection pad 36 in plan view. As described with reference to FIG. 2, since the gate interconnect 32 is disposed between the first connection pad 34 and the second connection pad 36 in plan view, at least a portion of the gate interconnect 32 is disposed under the conductive member 20. The conductive bonding material 18 is disposed between the semiconductor element 16 and the conductive member 20. The conductive bonding material 18 is disposed under the conductive member 20 and extends so as to at least partially overlap with each of the first connection pad 34 and the second connection pad 36.

The conductive member 20 may extend in the Y-axis direction beyond the semiconductor element 16 so as to be bonded to the conductive terminal 14 (refer to FIG. 1), which is located to avoid overlapping with the semiconductor element 16 in plan view.

Details of Bonding between Semiconductor Element and Conductive Member

FIG. 4 is a schematic cross-sectional view of the semiconductor device 10 taken along line F4-F4 of FIG. 3 showing the bonding of the semiconductor element 16 to the conductive member 20 via the conductive bonding material 18. For the sake of clear illustration, the semiconductor device 10 shown in FIG. 4 differs in scale from the semiconductor device 10 shown in FIG. 3.

The semiconductor element 16 further includes a passivation layer 60 formed on the gate interconnect 32. FIG. 4 does not show the transistor 70 (refer to FIG. 5) formed in the semiconductor layer 40. The passivation layer 60 may also be formed on the semiconductor layer 40. The source interconnect 46 formed on the semiconductor layer 40 is partially covered with the passivation layer 60. The passivation layer 60 includes the first pad opening 52, which exposes the first connection pad 34, and the second pad opening 54, which exposes the second connection pad 36. The passivation layer 60 may include at least one of a silicon nitride (SiN) film and a silicon dioxide (SiO₂) film. In an example, the passivation layer 60 may have a thickness of 0.5 to 2 μm.

The semiconductor element 16 may further include a first metal layer 62 disposed between the conductive bonding material 18 and the first connection pad 34 and a second metal layer 64 disposed between the conductive bonding material 18 and the second connection pad 36. The first metal layer 62 and the second metal layer 64 are embedded in the first pad opening 52 and the second pad opening 54, respectively. The first metal layer 62 and the second metal layer 64 may be formed in a greater region in plan view than the first pad opening 52 and the second pad opening 54, respectively. Accordingly, a portion of the first metal layer 62 and a portion of the second metal layer 64 may be formed on the passivation layer 60. The first metal layer 62 and the second metal layer 64 may be formed from any metal material, for example, one or more of Cu, Ti, Ni, and Au.

The organic film layer 58 is formed on the passivation layer 60. The organic film layer 58 is greater in thickness than the passivation layer 60. In addition, the organic film layer 58 may be greater in thickness than the gate interconnect 32 and the source interconnect 46. The organic film layer 58 is also formed on the first metal layer 62 and the second metal layer 64 and has a first opening 58A that exposes a portion of the first metal layer 62 and a second opening 58B that exposes a portion of the second metal layer 64.

The organic film layer 58 may be formed of a polyimide-based organic film. For example, the organic film layer 58 may be formed of a polybenzoxazole (PBO) film or a polyimide film. The organic film layer 58 may be a coating film formed by applying (for example, by spin coating) a liquid material. In this case, the organic film layer 58 may have a relatively flat surface even if a lower layer has a stepped structure. In an example, the organic film layer 58 may have a thickness of 5 to 10 μm.

The organic film layer 58 may define the uppermost layer of the semiconductor element 16. That is, the upper surface 16A of the semiconductor element 16 may correspond to the upper surface of the organic film layer 58. Thus, the organic film layer 58 may include the upper surface 16A of the semiconductor element 16.

The organic film layer 58 is formed of a film having a smaller internal stress than the passivation layer 60. In other words, the organic film layer 58 is formed of a material having a smaller Young's modulus than the material forming the passivation layer 60. In an example, the organic film layer 58 may be formed of a material having a Young's modulus that is less than one-tenth of a Young's modulus of the material forming the passivation layer 60.

The conductive bonding material 18 is disposed on the organic film layer 58. The opening 58A in the organic film layer 58 extends in the Z-axis direction from the upper surface 16A of the semiconductor element 16 (the upper surface of the organic film layer 58) to the surface of the first metal layer 62. The depth of the opening 58A in the Z-axis direction may correspond to the thickness of the organic film layer 58 formed on the first metal layer 62. The conductive bonding material 18 enters the opening 58A in the organic film layer 58 and contacts the first metal layer 62, which is formed on the first connection pad 34. In the same manner, the opening 58B in the organic film layer 58 extends in the Z-axis direction from the upper surface 16A of the semiconductor element 16 (the upper surface of the organic film layer 58) to the surface of the second metal layer 64. The depth of the opening 58B in the Z-axis direction may correspond to the thickness of the organic film layer 58 formed on the second metal layer 64. The conductive bonding material 18 enters the opening 58B in the organic film layer 58 and contacts the second metal layer 64, which is formed on the second connection pad 36. Thus, the conductive member 20, disposed on the conductive bonding material 18, is electrically connected to the first connection pad 34 and the second connection pad 36 via the conductive bonding material 18.

The conductive bonding material 18 is also disposed above the gate interconnect 32 in addition to above the first connection pad 34 and the second connection pad 36. The organic film layer 58 is disposed between the passivation layer 60 and the conductive bonding material 18 above the gate interconnect 32. Due to the presence of the organic film layer 58, the conductive bonding material 18 is not in direct contact with the passivation layer 60, which covers the gate interconnect 32.

FIG. 5 is a schematic cross-sectional view showing an example of the transistor 70 included in the semiconductor element 16. FIG. 5 shows an active region of transistor 70. In an example, the transistor 70 may be a MOSFET having a trench gate structure. The transistor 70 includes a gate electrode 72, a source electrode 74, and a drain electrode 76. In the present embodiment, the source electrode 74 and the drain electrode 76 correspond to the source interconnect 46 shown in FIG. 2 and the bottom electrode 38 shown in FIG. 1, respectively.

The semiconductor layer 40 may include a semiconductor substrate 78 and an epitaxial layer 80 formed on the semiconductor substrate 78. In an example, the semiconductor substrate 78 may be a Si substrate. The semiconductor substrate 78 corresponds to the drain region of the MOSFET. The epitaxial layer 80 may be a Si layer epitaxially grown on the Si substrate. The epitaxial layer 80 may include a drift region 82, a body region 84 formed on the drift region 82, and a source region 86 formed on the body region 84.

The drain region (semiconductor substrate 78) may be an n-type region containing an n-type impurity. The concentration of the n-type impurity in the drain region (semiconductor substrate 78) may be greater than or equal to 1×10¹⁸ cm⁻³ and less than or equal to 1×10²⁰ cm⁻³. The drain region (semiconductor substrate 78) may have a thickness that is greater than or equal to 50 μm and less than or equal to 450 μm.

The drift region 82 may be an n-type region containing an n-type impurity at a lower concentration than the drain region (semiconductor substrate 78). The concentration of the n-type impurity in the drift region 82 may be greater than or equal to 1×10¹⁵ cm⁻³ and less than or equal to 1×10¹⁸ cm⁻³. The drift region 82 may have a thickness that is greater than or equal to 1 μm and less than or equal to 25 μm.

The body region 84 may be a p-type region containing a p-type impurity. The concentration of the p-type impurity in the body region 84 may be greater than or equal to 1×10¹⁶ cm⁻³ and less than or equal to 1×10¹⁸ cm⁻³. The body region 84 may have a thickness that is greater than or equal to 0.2 μm and less than or equal to 1.0 μm.

The source region 86 may be an n-type region containing an n-type impurity at a higher concentration than the drift region 82. The concentration of the n-type impurity in the source region 86 may be greater than or equal to 1×10¹⁹ cm⁻³ and less than or equal to 1×10²¹ cm⁻³. The source region 86 may have a thickness that is greater than or equal to 0.1 μm and less than or equal to 1 μm.

In the present disclosure, n-type is also referred to as a first conductive type, and p-type is also referred to as a second conductive type. The n-type impurity may be, for example, phosphorus (P), arsenic (As), or the like. The p-type impurity may be, for example, boron (B), aluminum (Al), or the like.

As shown in FIG. 5, gate trenches 88 are formed in the semiconductor layer 40, and the gate electrode 72 is disposed in each gate trench 88. The gate trench 88 extends to the drift region 82 through the source region 86 and the body region 84 of the semiconductor layer 40. A field plate electrode 90 may be disposed in the gate trench 88 below the gate electrode 72. The field plate electrode 90 may be electrically connected to the source electrode 74. The gate electrode 72 and the field plate electrode 90 are embedded in the gate trench 88 together with an insulation layer 92. The gate electrode 72 and the field plate electrode 90 may be formed from conductive polysilicon. In an example, the insulation layer 92 may be formed from SiO₂. In addition to or instead of SiO₂, the insulation layer 92 may include a layer formed from an insulating material differing from SiO₂, which is, for example, SiN.

The source electrode 74 is electrically connected to the semiconductor layer 40 by a source contact plug 94. The source contact plug 94 may be disposed between two gate trenches 88. The semiconductor layer 40 further includes a contact region 96, which is a p-type region containing a p-type impurity. The source contact plug 94 extends to the body region 84 through the insulation layer 92 and the source region 86 and contacts the contact region 96. Thus, the source contact plug 94 electrically connects the source electrode 74, formed on the insulation layer 92, to the contact region 96 of the semiconductor layer 40.

The gate electrode 72 is electrically connected to the gate interconnect 32 shown in FIG. 2. In the present embodiment, the source electrode 74, which corresponds to the source interconnect 46 shown in FIG. 2, is electrically connected to the first connection pad 34 and the second connection pad 36.

The transistor 70 shown in FIG. 5, in which the drain electrode 76 is formed on the bottom surface of the semiconductor substrate 78, is a vertical transistor in which current flows in a direction intersecting the surface of the semiconductor substrate 78. The semiconductor device 10 of the present embodiment may be applied to any vertical transistor. In the example shown in FIG. 5, the transistor 70 is a Si MOSFET. In another example, the transistor 70 may be a SiC MOSFET.

Operation

The operation of the semiconductor device 10 of the present embodiment will be described below.

In the semiconductor device 10 of the present embodiment, the first connection pad 34 and the second connection pad 36 are electrically connected to the conductive member 20 via the conductive bonding material 18. The gate interconnect 32 is disposed between the first connection pad 34 and the second connection pad 36 in plan view. The passivation layer 60, formed on the gate interconnect 32, is separated from the conductive bonding material 18 by the organic film layer 58 that is greater in thickness than the passivation layer 60.

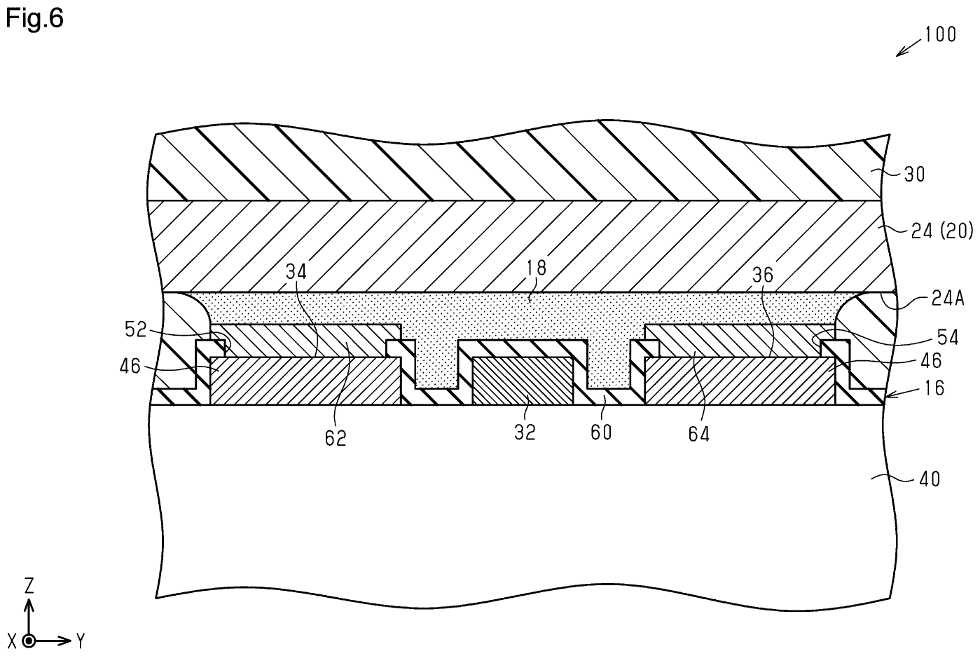

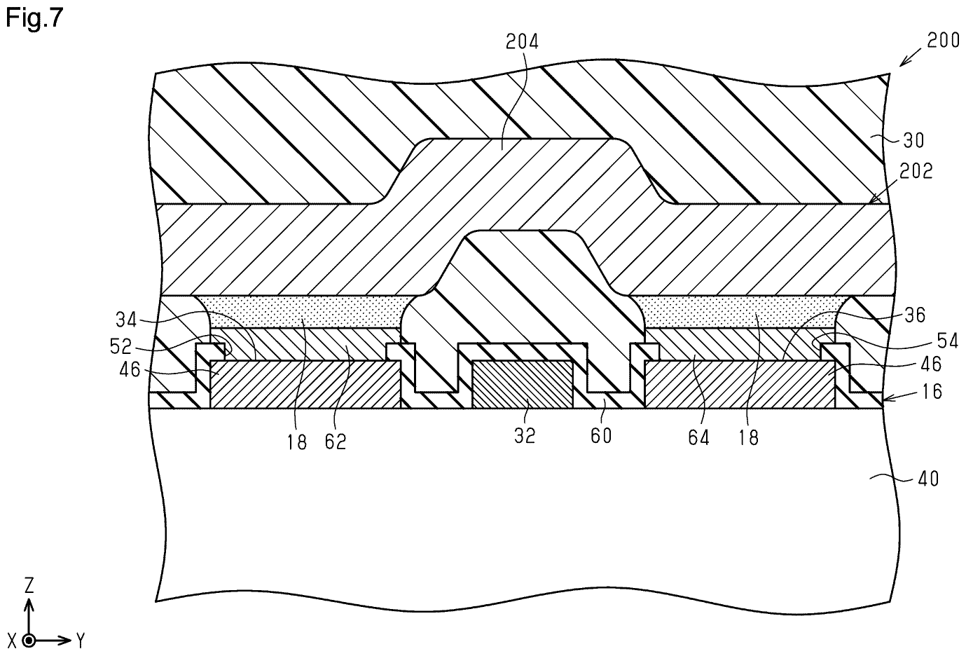

Thus, formation of cracks in the passivation layer 60, covering the gate interconnect 32, is limited. This limits formation of a short circuit of the gate interconnect 32 with the first connection pad 34 and the second connection pad 36. The advantages of the semiconductor device 10 of the present embodiment will be described below with reference to comparative examples shown in FIGS. 6 and 7.

FIG. 6 is a schematic cross-sectional view showing a comparative example of a semiconductor device 100. In FIG. 6, the same reference characters are given to those components that are the same as the corresponding components of the semiconductor device 10. Such components will not be described in detail.

In the semiconductor device 100, the passivation layer 60 is formed on the gate interconnect 32 in direct contact with the conductive bonding material 18. Thus, in the semiconductor device 100, the gate interconnect 32 and the conductive member 20 are insulated from each other by only the passivation layer 60. With this structure, when a thermal process is performed to bond the conductive bonding material 18, cracks are likely to be formed in the passivation layer 60. In an example, when the conductive bonding material 18 is solder, the temperature may change in a range from a room temperature to a temperature exceeding 200° C. in the reflow process. Such changes in temperature may induce formation of cracks in the passivation layer 60. Formation of cracks in the passivation layer 60 may form a short circuit between the gate interconnect 32 and the conductive member 20. In addition, in the semiconductor device 100, the distance between the passivation layer 60 and the conductive member 20 is short as compared to the semiconductor device 10. This further increases the likelihood of formation of a short circuit between the gate interconnect 32 and the conductive member 20.

FIG. 7 is a schematic cross-sectional view showing another comparative example of a semiconductor device 200. In FIG. 7, the same reference characters are given to those components that are the same as the corresponding components of the semiconductor device 10. Such components will not be described in detail.

The semiconductor device 200 differs from the semiconductor device 10 in that the semiconductor device 200 includes a conductive member 202 that is bent above the gate interconnect 32. In the semiconductor device 10, the gate interconnect 32, the first connection pad 34, and the second connection pad 36 are disposed below the flat bonding surface 24A of the first connecting part 24 of the conductive member 20. In the semiconductor device 200, the conductive member 202 includes a curved portion 204 located above the gate interconnect 32. Thus, all of the gate interconnect 32, the first connection pad 34, and the second connection pad 36 are not disposed below a single flat surface of the conductive member 202.

In the semiconductor device 200, the conductive member 202 including the curved portion 204 allows the passivation layer 60, covering the gate interconnect 32, and the curved portion 204 to be arranged without the conductive bonding material 18 disposed therebetween. The curved portion 204 is formed by bending the conductive member 202 to bulge in a direction away from the semiconductor element 16. In this case, after the conductive member 202 is bonded to the semiconductor element 16 by the conductive bonding material 18, the encapsulation member 30 is disposed between the passivation layer 60 and the conductive member 202. Thus, in the semiconductor device 200, the passivation layer 60 is not in contact with the conductive bonding material 18.

However, the semiconductor device 200 has the following disadvantages. (1) An additional process is necessary to form the curved portion 204 in the conductive member 202. (2) It is difficult to decrease the distance between the first connection pad 34 and the second connection pad 36 in order to position the curved portion 204 over the gate interconnect 32. Therefore, the semiconductor device 10 of the present embodiment is superior to the semiconductor device 200 in terms of manufacturing cost and size.

As described above, the semiconductor device 10 of the present embodiment limits formation of cracks in the passivation layer 60, which covers the gate interconnect 32, while limiting increases in manufacturing cost and size.

The semiconductor device 10 of the present embodiment has the following advantages.

(1) The first connection pad 34 and the second connection pad 36 are electrically connected to the conductive member 20 via the conductive bonding material 18. The gate interconnect 32 is disposed between the first connection pad 34 and the second connection pad 36 in plan view. The passivation layer 60, formed on the gate interconnect 32, is separated from the conductive bonding material 18 by the organic film layer 58 that is greater in thickness than the passivation layer 60.

Thus, formation of cracks in the passivation layer 60, covering the gate interconnect 32, is limited. This limits formation of a short circuit of the gate interconnect 32 with the first connection pad 34 and the second connection pad 36.

(2) The organic film layer 58 may have a thickness of 5 to 10 μm. Thus, the gate interconnect 32 and the conductive member 20 are separated by a relatively large distance so that formation of a short circuit between the gate interconnect 32 and the conductive member 20 is limited.

(3) The passivation layer 60 may have a thickness of 0.5 to 2 μm. Thus, the passivation layer 60 has a relatively small thickness so that formation of cracks due to the internal stress of the passivation layer 60 is limited.

(4) The organic film layer 58 may be formed of a material having a smaller Young's modulus than the material forming the passivation layer 60. This limits increases in the internal stress of the organic film layer 58 having a greater thickness than the passivation layer 60.

(5) The conductive member 20 may include the flat bonding surface 24A, facing the upper surface 16A of the semiconductor element 16. The gate interconnect 32, the first connection pad 34, and the second connection pad 36 may be disposed below the flat bonding surface 24A. Since the conductive member 20 is not bent above the gate interconnect 32, the semiconductor device 10 limits formation of cracks in the passivation layer 60, which covers the gate interconnect 32, while limiting increases in manufacturing cost and size.

(6) The semiconductor element 16 may further include the first metal layer 62 disposed between the conductive bonding material 18 and the first connection pad 34 and the second metal layer 64 disposed between the conductive bonding material 18 and the second connection pad 36. The first metal layer 62 and the second metal layer 64 are embedded in the first pad opening 52 and the second pad opening 54, respectively. This avoids direct contact of the conductive bonding material 18 with the first connection pad 34 and the second connection pad 36, thereby limiting reactions of the conductive bonding material 18 with the first connection pad 34 and the second connection pad 36.

(7) The first metal layer 62 and the second metal layer 64 may be formed in greater regions in plan view than the first pad opening 52 and the second pad opening 54, respectively. This limits contact of the passivation layer 60, which is located adjacent to the first pad opening 52 and the second pad opening 54, with the conductive bonding material 18.

(8) The organic film layer 58 may have the first opening 58A, which exposes a portion of the first metal layer 62, and the second opening 58B, which exposes a portion of the second metal layer 64. Accordingly, while the organic film layer 58 having a relatively large thickness is formed to separate the passivation layer 60, which covers the gate interconnect 32, from the conductive bonding material 18, the first connection pad 34 and the second connection pad 36 are electrically connected to the conductive bonding material 18.

### Second Embodiment

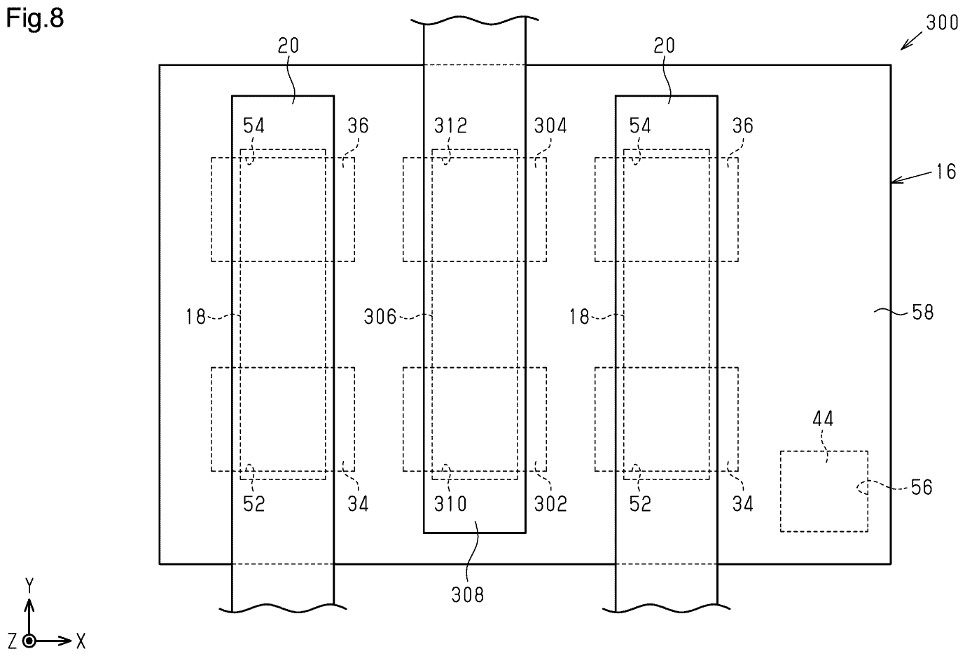

FIG. 8 is a schematic plan view showing an example of a semiconductor device 300 in a second embodiment. In FIG. 8, the same reference characters are given to those components that are the same as the corresponding components of the semiconductor device 10. Such components will not be described in detail.

The semiconductor element 16 of the semiconductor device 300 further includes a third connection pad 302 and a fourth connection pad 304 that are separated from each other in the Y-axis direction in plan view. The semiconductor device 300 further includes a second conductive bonding material 306 and a second conductive member 308 disposed on the second conductive bonding material 306. The second conductive bonding material 306 is disposed on the semiconductor element 16 and at least partially overlaps with the third connection pad 302 and the fourth connection pad 304 in plan view. To be distinguished from the second conductive bonding material 306 and the second conductive member 308, the conductive bonding material 18 may be referred to as a first conductive bonding material, and the conductive member 20 may be referred to as a first conductive member.

The passivation layer 60 includes a pad opening 310 that exposes the third connection pad 302 and a pad opening 312 that exposes the fourth connection pad 304.

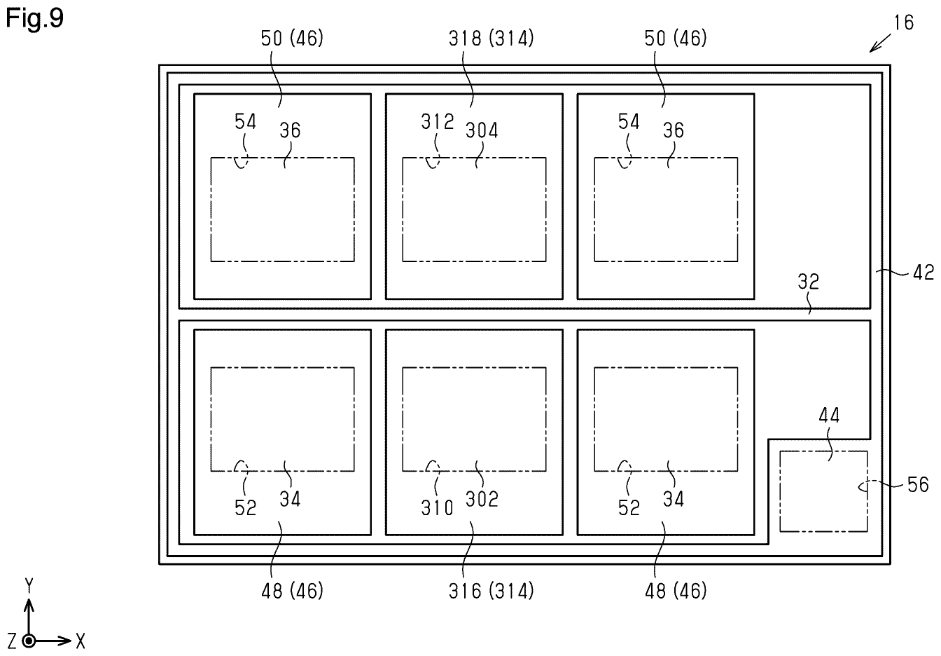

FIG. 9 is a schematic plan view showing an example of the semiconductor element 16 of the semiconductor device 300 in the second embodiment. As shown in FIG. 9, the semiconductor element 16 may further include a drain interconnect 314. The drain interconnect 314 is surrounded by the peripheral gate interconnect 42 in plan view and is separated from the gate interconnect 32, the peripheral gate interconnect 42, the gate pad 44, and the source interconnect 46. The drain interconnect 314 may include a first part 316 and a second part 318 that are separated from each other in the Y-axis direction by the gate interconnect 32 extending in the X-axis direction. In the example shown in FIG. 2, the gate interconnect 32 is divided at the center of the semiconductor element 16. In the example shown in FIG. 9, the gate interconnect 32 does not necessarily have to be divided.

In FIG. 9, the organic film layer 58 and the passivation layer 60 are omitted to facilitate understanding. In FIG. 9, the double-dashed lines indicate the pad openings 52, 54, 56, 310, and 312 formed in the passivation layer 60. The pad opening 310 and the pad opening 312 are respectively formed on the first part 316 and the second part 318 of the drain interconnect 314.

As shown in FIG. 9, since the gate interconnect 32 is disposed between the third connection pad 302 and the fourth connection pad 304 in plan view, at least a portion of the gate interconnect 32 is disposed under the second conductive member 308 shown in FIG. 8. Thus, the second conductive bonding material 306 at least partially overlaps the gate interconnect 32 in plan view.

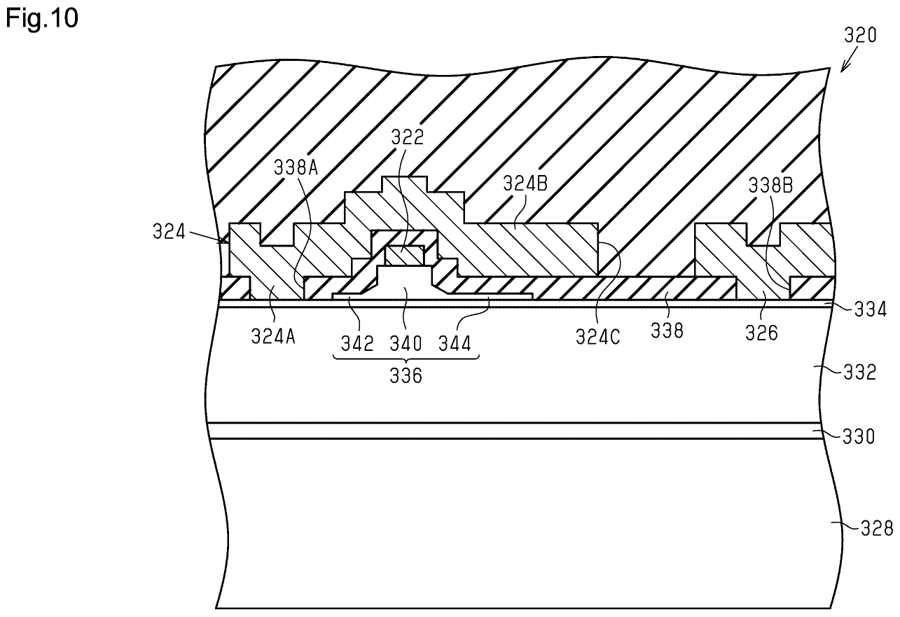

FIG. 10 is a schematic cross-sectional view showing an example of a transistor 320 included in the semiconductor element 16 shown in FIG. 9. FIG. 10 shows an active region of transistor 320. In an example, the transistor 320 may be a high-electron-mobility transistor including a nitride semiconductor. The transistor 320 includes a gate electrode 322, a source electrode 324, and a drain electrode 326. In the present embodiment, the semiconductor element 16 does not necessarily have to include a bottom electrode such as the bottom electrode 38 shown in FIG. 1.

The transistor 320 may include a semiconductor substrate 328, a buffer layer 330 formed on the semiconductor substrate 328, an electron transit layer 332 formed on the buffer layer 330, and an electron supply layer 334 formed on the electron transit layer 332.

The semiconductor substrate 328 may be formed of silicon (Si), silicon carbide (SiC), GaN, sapphire, or other substrate materials. In an example, the semiconductor substrate 328 may be a Si substrate. The semiconductor substrate 328 may have a thickness that is, for example, greater than or equal to 200 μm and less than or equal to 1500 μm.

The buffer layer 330 may be disposed between the semiconductor substrate 328 and the electron transit layer 332. In an example, the buffer layer 330 may be formed from any material that facilitates epitaxial growth of electron transit layer 332. The buffer layer 330 may include one or more nitride semiconductor layers. In an example, the buffer layer 330 may include at least one of an aluminum nitride (AlN) layer, an aluminum gallium nitride (AlGaN) layer, and a graded AlGaN layer having different aluminum (Al) compositions. For example, the buffer layer 330 may include a single AlN layer, a single AlGaN layer, a layer having a superlattice structure of AlGaN/GaN, a layer having a superlattice structure of AlN/AlGaN, or a layer having a superlattice structure of AlN/GaN.

The electron transit layer 332 is formed from a nitride semiconductor. The electron transit layer 332 may be, for example, a GaN layer. The electron transit layer 332 may have a thickness that is, for example, greater than or equal to 0.5 μm and less than or equal to 2 μm.

The electron supply layer 334 is formed from a nitride semiconductor having a band gap that is larger than that of the electron transit layer 332. The electron supply layer 334 may be, for example, an AlGaN layer. The band gap increases as the composition of Al increases. Therefore, the electron supply layer 334, which is an AlGaN layer, has a larger band gap than the electron transit layer 332, which is a GaN layer. In an example, the electron supply layer 334 is formed from AlₓGa₁₋ₓN, where 0.1<x<0.4, and more preferably, 0.1<x<0.3. The electron supply layer 334 may have a thickness that is greater than or equal to 5 nm and less than or equal to 20 nm.

The electron transit layer 332 and the electron supply layer 334 are formed from nitride semiconductors having different lattice constants. Therefore, the nitride semiconductor forming the electron transit layer 332 (e.g., GaN) and the nitride semiconductor forming the electron supply layer 334 (e.g., AlGaN) form a lattice-mismatching heterojunction. The energy level of the conduction band of the electron transit layer 332 in the vicinity of the heterojunction interface is lower than the Fermi level due to spontaneous polarization of the electron transit layer 332 and the electron supply layer 334 and piezoelectric polarization caused by crystal distortion in the vicinity of the heterojunction interface. Accordingly, at a location close to the heterojunction interface between the electron transit layer 332 and the electron supply layer 334 (e.g., in a range of approximately a few nanometers from the interface), a two-dimensional electronic gas (2DEG) spreads in the electron transit layer 332. The 2DEG is used as a current passage (channel) of the transistor 320.

The transistor 320 further includes a gate layer 336 and a passivation layer 338 that are formed on the electron supply layer 334. The gate layer 336 is formed from a nitride semiconductor containing an acceptor impurity. The gate layer 336 may be, for example, a GaN layer having a smaller band gap than the electron supply layer 334, which is an AlGaN layer. In an example, the gate layer 336 is a GaN layer (p-type GaN layer) doped with an acceptor impurity. The acceptor impurity may include at least one of zinc (Zn), magnesium (Mg), and carbon (C). The maximum concentration of the acceptor impurity in the gate layer 336 is, for example, greater than or equal to 7×10¹⁸ cm⁻³ and less than or equal to 1×10²⁰ cm⁻³.

The passivation layer 338 covers the electron supply layer 334, the gate layer 336, and the gate electrode 322 and has a source opening 338A and a drain opening 338B. The source electrode 324 is in contact with the electron supply layer 334 through the source opening 338A. The drain electrode 326 is in contact with the electron supply layer 334 through the drain opening 338B.

In the example shown in FIG. 10, the gate layer 336 may include a gate ridge 340, on which the gate electrode 322 is formed, and a source-side extension 342 and a drain-side extension 344, each of which has a smaller thickness than the gate ridge 340. The source-side extension 342 and the drain-side extension 344 extend outward from the gate ridge 340 in plan view.

The source-side extension 342 extends from the gate ridge 340 toward the source opening 338A in plan view. The source-side extension 342 does not reach the source opening 338A. The source-side extension 342 is separated from the source electrode 324 by the passivation layer 338.

The drain-side extension 344 extends from the gate ridge 340 toward the drain opening 338B in plan view. The drain-side extension 344 does not reach the drain opening 338B. The drain-side extension 344 is separated from the drain electrode 326 by the passivation layer 338.

The gate ridge 340 is disposed between the source-side extension 342 and the drain-side extension 344 and is formed integrally with the source-side extension 342 and the drain-side extension 344.

The gate ridge 340 corresponds to a relatively thick portion of the gate layer 336. The gate ridge 340 may have a thickness that is, for example, greater than or equal to 80 nm and less than or equal to 150 nm.

The gate electrode 322 is formed on the gate ridge 340. The gate electrode 322 may have a thickness that is, for example, greater than or equal to 50 nm and less than or equal to 200 nm. The gate electrode 322 is formed of one or more metal layers, which is, for example, a TiN layer. Alternatively, the gate electrode 322 may include a first layer formed from Ti and a second layer formed from TiN and disposed on the first layer. The gate electrode 322 may have a thickness that is, for example, greater than or equal to 50 nm and less than or equal to 200 nm. The gate electrode 322 may form a Schottky junction with the gate layer 336.

The source electrode 324 may include a source contact plug 324A that fills the source opening 338A and a source field plate 324B that covers the passivation layer 338. The source field plate 324B may be formed integrally with the source contact plug 324A. The source field plate 324B includes an end 324C located between the drain opening 338B and the gate layer 336 in plan view. In a state in which no gate voltage is applied to the gate electrode 322, that is, in the zero bias state, when a drain voltage is applied to the drain electrode 326, the source field plate 324B reduces the concentration of electric field in the vicinity of the end of the gate electrode 322.

At least a portion of the source electrode 324 fills the source opening 338A. This allows the source electrode 324 to be in ohmic contact with the 2DEG located immediately below the electron supply layer 334 through the source opening 338A. In the same manner, at least a portion of the drain electrode 326 fills the drain openings 338B. This allows the drain electrode 326 to be in ohmic contact with the 2DEG located immediately below the electron supply layer 334 through the drain opening 338B.

One or more interconnect layers (not shown) may be formed on the transistor 320. Thus, the gate electrode 322, the source electrode 324, and the drain electrode 326 of the transistor 320 are electrically connected to the gate interconnect 32, the source interconnect 46, and the drain interconnect 314 shown in FIG. 9, respectively. Accordingly, the first connection pad 34 and the second connection pad 36 are electrically connected to the source electrode 324, and the third connection pad 302 and the fourth connection pad 304 are electrically connected to the drain electrode 326.

In the transistor 320 shown in FIG. 10, both the source electrode 324 and the drain electrode 326 are formed above the semiconductor substrate 328. Thus, the transistor 320 is a lateral transistor in which current flows in a direction parallel to the surface of the semiconductor substrate 328. In the example shown in FIG. 10, the transistor 320 is a GaN HEMT. However, the semiconductor device 300 of the present embodiment may be applied to any lateral transistor.

Also, in the semiconductor device 300 of the second embodiment, the passivation layer 60, formed on the gate interconnect 32, is separated from the second conductive bonding material 306 by the organic film layer 58 that is greater in thickness than the passivation layer 60.

Thus, formation of cracks in the passivation layer 60, covering the gate interconnect 32, is limited. This limits formation of a short circuit of the gate interconnect 32 with the third connection pad 302 and the fourth connection pad 304.

In addition to the advantages described above, the semiconductor device 300 of the second embodiment has advantages similar to the advantages (1) to (8) of the semiconductor device 10 in the first embodiment.

### Modified Examples

The embodiments may be modified as follows.

The layout of the gate interconnect 32 and the source interconnect 46 of the semiconductor element 16 shown in FIG. 2 may be changed in any manner. For example, the peripheral gate interconnect 42 does not necessarily have to have a closed loop along the edges of the semiconductor element 16. The peripheral gate interconnect 42 may be divided at any position.

The layout of the source interconnect 46 and the drain interconnect 314 of the semiconductor element 16 shown in FIG. 9 may be changed in any manner. For example, the number of source interconnects 46 and the number of drain interconnects 314 may differ from (for example, may be greater than) those shown in FIG. 9.

In FIG. 1, a metal clip is shown as an example of the conductive member 20. Alternatively, the conductive member 20 may be in the form of a metal film.

The passivation layer 60 may be formed of a polyimide-based organic film. The passivation layer 60 may be formed from a material having a relatively small Young's modulus so that the internal stress of the passivation layer 60 is reduced. This limits formation of cracks in the passivation layer 60.

The conductivity type of each region in the semiconductor layer 40 may be inverted. That is, a p-type region may be changed to an n-type region, and an n-type region may be changed to a p-type region.

In the transistor 70 shown in FIG. 5, the gate electrode 72 and the field plate electrode 90 are disposed in the gate trench 88. However, the field plate electrode 90 does not necessarily have to be disposed in the gate trench 88.

In the transistor 320 shown in FIG. 10, the gate layer 336 includes the gate ridge 340. However, the gate layer 336 does not necessarily have to include the source-side extension 342 and the drain-side extension 344.

One or more of the various examples described in this specification may be combined within a range where there is no technical inconsistency.

In this specification, “at least one of A and B” should be understood to mean “only A, or only B, or both A and B”.

In this specification, the term “on” includes the meaning of “above” in addition to the meaning of “on” unless otherwise clearly indicated in the context. Therefore, the phrase “first layer formed on second layer” is intended to mean that the first layer may be formed on the second layer in contact with the second layer in one embodiment and that the first layer may be located above the second layer without contacting the second layer in another embodiment. In other words, the term “on” does not exclude a structure in which another layer is formed between the first layer and the second layer.

The directional terms used in this specification such as “vertical,” “horizontal,” “above,” “below,” “top,” “bottom,” “front,” “back,” “longitudinal,” “lateral,” “left,” “right,” “front,” and “back” will depend upon a particular orientation of the device being described and illustrated. The present disclosure may include various alternative orientations. Therefore, the directional terms should not be narrowly construed.

For example, the Z-axis direction as referred to in this specification does not necessarily have to be the vertical direction and does not necessarily have to fully conform to the vertical direction. For example, the X-axis direction may conform to the vertical direction. The Y-axis direction may conform to the vertical direction.

### CLAUSES

The technical aspects that are understood from the present disclosure will hereafter be described. It should be noted that, for the purpose of facilitating understanding with no intention to limit, elements described in clauses are given the reference characters of the corresponding elements of the embodiments. The reference characters used as examples to facilitate understanding, and the elements in each clause are not limited to those elements given with the reference characters.

Clause 1

A semiconductor device, including:
a semiconductor element (16) including
   a transistor (70) including a gate electrode (72), a source electrode (74), and a drain electrode (76),
   a gate interconnect (32) electrically connected to the gate electrode (72) and extending in a first direction,
   a first connection pad and a second connection pad (34, 36) electrically connected to one of the source electrode (74) and the drain electrode (76), the first connection pad and the second connection pad (34, 36) being separated from each other in a second direction orthogonal to the first direction in plan view,
   a passivation layer (60) formed on the gate interconnect (32), and
   an organic film layer (58) formed on the passivation layer (60);
a conductive bonding material (18) disposed on the semiconductor element (16) and at least partially overlapping with the gate interconnect (32), the first connection pad (34), and the second connection pad (36) in plan view; and
a conductive member (20) disposed on the conductive bonding material (18), in which
the first connection pad (34) and the second connection pad (36) are electrically connected to the conductive member (20) via the conductive bonding material (18), the gate interconnect (32) is disposed between the first connection pad (34) and the second connection pad (36) in plan view, and
the passivation layer (60) formed on the gate interconnect (32) is separated from the conductive bonding material (18) by the organic film layer (58) that is greater in thickness than the passivation layer (60).

Clause 2

The semiconductor device according to clause 1, in which the organic film layer (58) has a thickness of 5 to 10 μm.

Clause 3

The semiconductor device according to clause 1 or 2, in which the passivation layer (60) has a thickness of 0.5 to 2 μm.

Clause 4

The semiconductor device according to any one of clauses 1 to 3, in which the organic film layer (58) is formed of a polyimide-based organic film.

Clause 5

The semiconductor device according to any one of clauses 1 to 4, in which the organic film layer (58) is formed of polybenzoxazole or polyimide.

Clause 6

The semiconductor device according to any one of clauses 1 to 5, in which the passivation layer (60) includes at least one of a SiN film or a side SiO₂ film.

Clause 7

The semiconductor device according to any one of clauses 1 to 6, in which the organic film layer (58) is formed of a material having a smaller Young's modulus than a material forming the passivation layer (60).

Clause 8

The semiconductor device according to any one of clauses 1 to 7, in which the organic film layer (58) is formed of a material having a Young's modulus that is less than one-tenth of a Young's modulus of a material forming the passivation layer (60).

Clause 9

The semiconductor device according to any one of clauses 1 to 8, in which
the conductive member (20) includes a flat bonding surface (24A) facing an upper surface of the semiconductor element (16), and
the gate interconnect (32), the first connection pad (34), and the second connection pad (36) are disposed below the flat bonding surface (24A).

Clause 10

The semiconductor device according to any one of clauses 1 to 9, in which the conductive member (20) includes a copper clip.

Clause 11

The semiconductor device according to any one of clauses 1 to 10, in which the conductive bonding material (18) is solder.

Clause 12

The semiconductor device according to any one of clauses 1 to 11, in which
the passivation layer (60) includes a first pad opening (52) that exposes the first connection pad (34) and a second pad opening (54) that exposes the second connection pad (36),
the semiconductor element (16) further includes a first metal layer (62) disposed between the conductive bonding material (18) and the first connection pad (34) and a second metal layer (64) disposed between the conductive bonding material (18) and the second connection pad (36), and
the first metal layer (62) and second metal layer (64) are respectively embedded in the first pad opening (52) and the second pad opening (54).

Clause 13

The semiconductor device according to clause 12, in which the first metal layer (62) and the second metal layer (64) are formed in a greater region in plan view than the first pad opening (52) and the second pad opening (54), respectively.

Clause 14

The semiconductor device according to clause 12 or 13, in which the organic film layer (58) has a first opening (58A) that exposes a portion of the first metal layer (62) and a second opening (58B) that exposes a portion of the second metal layer (64).

Clause 15

The semiconductor device according to any one of clauses 1 to 14, in which the transistor (70; 320) includes a Si MOSFET, a SiC MOSFET, or a GaN HEMT.

Clause 16

The semiconductor device according to any one of clauses 1 to 14, in which the transistor (70) includes a vertical transistor.

Clause 17

The semiconductor device according to any one of clauses 1 to 15, in which
the conductive member (20) is a first conductive member (20),
the conductive bonding material (18) is a first conductive bonding material (18),
the first connection pad (34) and the second connection pad (36) are electrically connected to the source electrode (324),
the semiconductor element (16) further includes a third connection pad (302) and a fourth connection pad (304) electrically connected to the drain electrode (326),
the third connection pad (302) and the fourth connection pad (304) are separated from each other in the second direction in plan view,
the semiconductor device further includes:
   a second conductive bonding material (306) disposed on the semiconductor element (16) and at least partially overlapping with the gate interconnect (32), the third connection pad (302), and the fourth connection pad (304) in plan view; and
   a second conductive member (308) disposed on the second conductive bonding material (306),
the third connection pad (302) and the fourth connection pad (304) are electrically connected to the second conductive member (308) via the second conductive bonding material (306), and the gate interconnect (32) is disposed between the third connection pad (302) and the fourth connection pad (304) in plan view, and
the passivation layer (60) formed on the gate interconnect (32) is separated from the second conductive bonding material (306) by the organic film layer (58) that is greater in thickness than the passivation layer (60).

Clause 18

The semiconductor device according to clause 17, in which the transistor (320) includes a lateral transistor.

Clause 19

The semiconductor device according to any one of clauses 1 to 5, in which the passivation layer (60) is formed of a polyimide-based organic film.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
a semiconductor element including
a transistor including a gate electrode, a source electrode, and a drain electrode,
a gate interconnect electrically connected to the gate electrode and extending in a first direction,
a first connection pad and a second connection pad electrically connected to one of the source electrode and the drain electrode, the first connection pad and the second connection pad being separated from each other in a second direction orthogonal to the first direction in plan view,
a passivation layer formed on the gate interconnect, and
an organic film layer formed on the passivation layer;
a conductive bonding material disposed on the semiconductor element and at least partially overlapping with the gate interconnect, the first connection pad, and the second connection pad in plan view; and
a conductive member disposed on the conductive bonding material, wherein
the first connection pad and the second connection pad are electrically connected to the conductive member via the conductive bonding material,
the gate interconnect is disposed between the first connection pad and the second connection pad in plan view, and
the passivation layer formed on the gate interconnect is separated from the conductive bonding material by the organic film layer that is greater in thickness than the passivation layer.

2. The semiconductor device according to claim 1, wherein the organic film layer has a thickness of 5 to 10 μm.

3. The semiconductor device according to claim 1, wherein the passivation layer has a thickness of 0.5 to 2 μm.

4. The semiconductor device according to claim 1, wherein the organic film layer is formed of a polyimide-based organic film.

5. The semiconductor device according to claim 1, wherein the organic film layer is formed of polybenzoxazole or polyimide.

6. The semiconductor device according to claim 1, wherein the passivation layer includes at least one of a SiN film or a SiO₂ film.

7. The semiconductor device according to claim 1, wherein the organic film layer is formed of a material having a smaller Young's modulus than a material forming the passivation layer.

8. The semiconductor device according to claim 1, wherein the organic film layer is formed of a material having a Young's modulus that is less than one-tenth of a Young's modulus of a material forming the passivation layer.

9. The semiconductor device according to claim 1, wherein
the conductive member includes a flat bonding surface facing an upper surface of the semiconductor element, and
the gate interconnect, the first connection pad, and the second connection pad are disposed below the flat bonding surface.

10. The semiconductor device according to claim 1, wherein the conductive member includes a copper clip.

11. The semiconductor device according to claim 1, wherein the conductive bonding material is solder.

12. The semiconductor device according to claim 1, wherein
the passivation layer includes a first pad opening that exposes the first connection pad and a second pad opening that exposes the second connection pad,
the semiconductor element further includes a first metal layer disposed between the conductive bonding material and the first connection pad and a second metal layer disposed between the conductive bonding material and the second connection pad, and
the first metal layer and second metal layer are respectively embedded in the first pad opening and the second pad opening.

13. The semiconductor device according to claim 12, wherein the first metal layer and the second metal layer are formed in a greater region in plan view than the first pad opening and the second pad opening, respectively.

14. The semiconductor device according to claim 12, wherein the organic film layer includes a first opening that exposes a portion of the first metal layer and a second opening that exposes a portion of the second metal layer.

15. The semiconductor device according to claim 1, wherein the transistor includes a silicon (Si) metal-oxide-semiconductor field-effect transistor (MOSFET), a silicon carbide (SiC) MOSFET, or a gallium nitride (GaN) high-electron-mobility transistor (HEMT).

16. The semiconductor device according to claim 1, wherein the transistor includes a vertical transistor.

17. The semiconductor device according to claim 1, wherein
the conductive member is a first conductive member,
the conductive bonding material is a first conductive bonding material,
the first connection pad and the second connection pad are electrically connected to the source electrode,
the semiconductor element further includes a third connection pad and a fourth connection pad electrically connected to the drain electrode,
the third connection pad and the fourth connection pad are separated from each other in the second direction in plan view,
the semiconductor device further comprises:
a second conductive bonding material disposed on the semiconductor element and at least partially overlapping with the gate interconnect, the third connection pad, and the fourth connection pad in plan view; and
a second conductive member disposed on the second conductive bonding material,
the third connection pad and the fourth connection pad are electrically connected to the second conductive member via the second conductive bonding material, the gate interconnect is disposed between the third connection pad and the fourth connection pad in plan view, and
the passivation layer formed on the gate interconnect is separated from the second conductive bonding material by the organic film layer that is greater in thickness than the passivation layer.

18. The semiconductor device according to claim 17, wherein the transistor includes a lateral transistor.
